(19) United States
(12) Patent Application Publication
(10) Pub. No.: US 2003/0232463 A1
(43) Pub. Date: Dec. 18, 2003

(54) Carbon foam heat exchanger for intedgrated circuit

(75) Inventor: Howard Davidson, San Carlos, CA (US)

Correspondence Address: MEYERTONS, HOOD, KIVLIN, KOWERT & GOETZEL, P.C., P.O. BOX 398, AUSTIN, TX, 78767-0398, US

(73) Assignee: Sun Microsystems, Inc.

(21) Appl. No.: 10/600,945

(22) Filed: Jun. 20, 2003

Related U.S. Application Data
(63) Continuation of application No. 10/094,459, filed on Mar. 8, 2002.

(51) Int. Cl. H01L 21/44; H01L 21/48; H01L 21/50

(52) U.S. Cl. 438/122; 438/118; 438/612

(57) ABSTRACT

A graphitic carbon foam material may have application as a heat sink or heat spreader for an integrated circuit. The graphitic carbon foam material may be coupled directly to an integrated circuit by a number of different methods. The graphitic carbon foam material may be disposed within a chamber such that a heat exchange fluid may be directed through the graphitic carbon foam material.

### PRIORITY CLAIM

This application claims the benefit of U.S. patent application Ser. No. 10/094,459 entitled “Carbon Foam Heat Exchanger for Integrated Circuit,” filed Mar. 8, 2002.

### BACKGROUND OF THE INVENTION

1. Field of the Invention

The present invention generally relates to a carbon foam heat exchanger. More particularly, the invention relates to a carbon foam heat exchanger used in conjunction with an integrated circuit to provide a method of cooling an integrated circuit.

2. Description of the Related Art

Certain electrical components, such as the integrated circuits and power devices in conventional computer systems, generate a substantial amount of heat during operation. If the circuit temperature is not maintained at or below the specified maximum junction temperature the circuit will not function properly, and the life will be reduced.

There may be various methods of cooling integrated circuits. One method may be the direction of a cooling stream of air over the integrated circuit. One or more fans may be placed within a computer system to direct air through the computer system. The air may be drawn into the computer system, directed across the integrated circuit, and exhausted out of the computer system into the environment.

The airflow from fans over the surface of the integrated circuit package can provide sufficient cooling for low power integrated circuits. However, integrated circuits that produce greater amounts of heat require more effective methods of removing heat from the circuit package. One method of achieving greater cooling using air circulation may be to increase the surface area coupling heat from the package to the air. This may be accomplished by the addition of a heat sink to the integrated circuit. For good performance, a heat sink should have as much surface area as possible within the limitations of the pressure developed by the air mover. It is also desirable to fabricate the heat sink from a material with high thermal conductivity so that as much of the area as possible participates in heat transfer. Copper and aluminum are common materials for this application. Copper has a thermal conductivity of about 4 W/cm·K, while aluminum is about 2.4 W/cm·K. Other materials, such as diamond, with a thermal conductivity of about 20 W/cm·K may be used to improve the heat dissipation of the heat sinks, but the use of diamond may not be practical because of cost and fabrication difficulty.

Diamond has a high thermal conductivity as stated. Type IIa diamonds have the highest thermal conductivity, about 24 W/cm·K, but are expensive and only available in relatively small sizes. A hybrid diamond/copper composite material has been produced which provides an improved heat sink for integrated circuits. U.S. Pat. No. 5,783,316 to Colella et al., which is incorporated herein by reference, provides further information on the diamond-copper hybrid material.

It may be desirable to utilize other materials as heat sinks. Thermal conductivity, ease of fabrication and coupling to an integrated circuit, and cost of the heat sink may be important parameters in the selection of heat sink materials.

### SUMMARY OF THE INVENTION

In an embodiment, a carbon foam material may be used as a heat exchange material to convey heat away from an integrated circuit. The carbon foam material may be a nanostructured carbon foam material. The carbon foam material may be shaped such that the carbon foam material substantially contacts the area of heat generation of an integrated circuit to provide dissipation of heat away from the integrated circuit. The carbon foam material may be coupled in several different ways, including, but not limited to soldering, brazing and electroplating. The heat generated by the integrated circuit may pass freely from the integrated circuit to the carbon foam material. The carbon foam may dissipate the transferred heat to the environment.

A cooling fluid may be passed through the carbon foam material to dissipate the heat transferred to the carbon foam material from the integrated circuit. The cooling fluid may be any fluid that provides a method of transferring the heat conducted to the carbon foam material to the environment. Examples of heat exchange fluids include, but are not limited to, ambient air, inert gases, gaseous organic materials, liquid organic materials, liquid inorganic materials, or other fluids, whether gas or liquid, which may dissipate heat away from the carbon foam material.

A method of directing the heat exchange fluid may be required in some instances. The carbon foam material may be enclosed within a chamber such that the heat exchange fluid is directed to substantially pass through the carbon foam material. In the case of ambient air, the heated medium may be discharged to the environment. If a liquid is used it may, in general, be confined to a closed loop with a secondary heat exchanger to transfer heat to the environment.

### BRIEF DESCRIPTION OF THE DRAWINGS

Other objects and advantages of the invention will become apparent upon reading the following detailed description and upon reference to the accompanying drawings in which:

FIG. 1 depicts a schematic drawing of a carbon foam heat sink coupled to an integrated circuit;

FIG. 2 depicts a schematic drawing of an integrated circuit with a metal silicide, solderable metal and coating coupled to the integrated circuit; and

FIG. 3 depicts a schematic drawing of a carbon foam heat sink coupled to an integrated circuit, wherein the carbon foam heat sink is disposed within a chamber.

### DETAILED DESCRIPTION OF THE INVENTION

In an embodiment, a carbon foam material may be used as a heat exchange material to radiate heat away from an integrated circuit. The carbon foam material may be produced by a number of different methods. One method of producing a graphitic carbon foam material may be found in U.S. Pat. No. 5,300,272 to Simandl, et al., which is incorporated herein by reference. Microcellular carbon foam may be produced by a phase inversion of polyacrylonitrile to form a gel and then removing the solvent to provide a porous foam. The polyacrylonitrile may be cross-linked, cured, and heated in an inert atmosphere to carbonize the polyacrylonitrile. The polyacrylonitrile-based carbon foam may be converted to graphitic carbon foam at temperatures greater than about 1000° C. Graphitic carbon foam may be defined herein as carbon foam that include the three dimensional order characteristics of polycrystalline graphite and properties associated with graphite such as, but not limited to, high density, low electrical resistivity, and high thermal conductivity.

A second method of producing graphitic carbon foam may be found in U.S. Pat. No. 6,033,506 to Klett, which is incorporated herein by reference. Mesophase or isotropic pitch-based carbon foam may be converted, in an inert atmosphere, to graphitic carbon foam at temperatures greater than about 1000° C. The method may allow the formation of various shapes. The carbon foam may be produced with a smooth surface to improve heat transfer by maximizing contact points. The specific thermal conductivity, which is the thermal conductivity divided by the specific gravity, of a graphitic carbon foam may be greater than about 0.50 W/cm·K. The specific thermal conductivity for copper is about 0.50 W/cm·K.

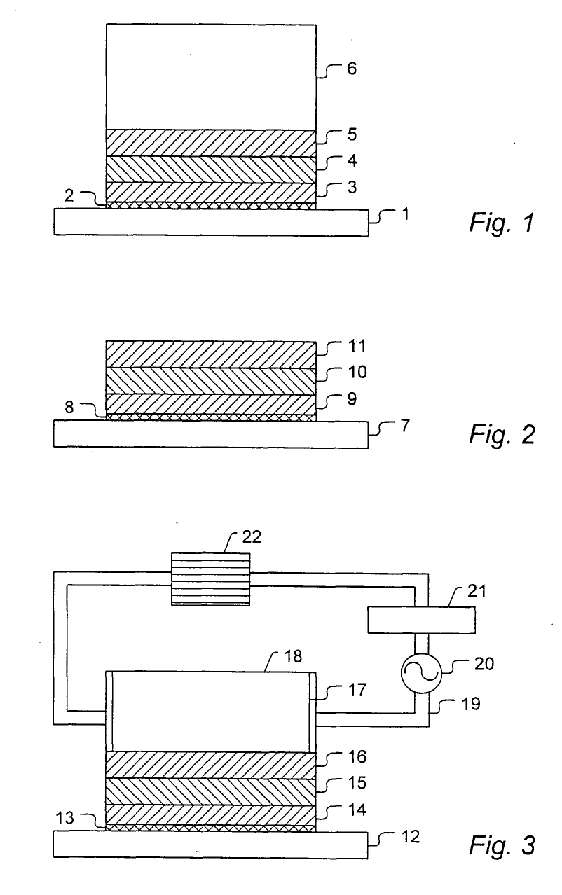

Referring to FIG. 1, carbon foam material 6 may be coupled to an integrated circuit 2, on substrate 1, to direct the heat generated by the integrated circuit away from the integrated circuit. The carbon foam material may be coated with metal 5. In an embodiment, the carbon foam material may be coupled to the integrated circuit by way of solder 4. The integrated circuit may be backsputtered with an inert gas to prepare the integrated circuit surface for coupling of the carbon foam. An inert gas may be any gas that does not chemically react with the integrated circuit surface. An inert gas includes, but is not limited to, helium, nitrogen, argon, krypton, neon, or mixtures thereof. The backsputtering may be conducted in a chamber that provides an environment substantially free of contaminants. The integrated circuit may be sputtered with a reactive metal to provide a reactive metal surface of from about 0.01 microns to about 0.1 microns in depth on the surface of the integrated circuit. The reactive metal sputtered onto the surface of the integrated circuit may be converted to silicide 3.

Silicide formation is well known in the art. Silicides may be formed from metals including, but not limited to, nickel, titanium, tungsten, iron, cobalt, ruthenium, rhodium, palladium, osmium, iridium, scandium, vanadium, chromium, zirconium, tantalum, manganese, copper, gold, silver, and zinc. Further information on silicide formation may be found in U.S. Pat. No. 6,168,980 to Yamazaki, et al., U.S. Pat. No. 6,197,646 to Goto, et al., and U.S. Pat. No. 6,198,143 to Ohsaki, all of which are incorporated herein by reference. The formation of the silicide may improve thermal contact between the carbon foam material and the integrated circuit.

Referring to FIG. 2, integrated circuit 8, on substrate 7, may include solder 10 disposed upon silicide 9 by sputtering. A depth of the solder may be from about 0.1 to about 10 microns. A solder may include a metal or an alloy of two or more metals. Examples of metals include, but are not limited to, copper, nickel, gold or silver. Examples of metal alloys include, but are not limited to, combinations of copper, nickel, gold, silver, lead, silicon, indium, bismuth, titanium, tin, and/or rare earth elements. Capping layer 11 may be disposed upon solder 10 to reduce oxidation of the surface during storage. A capping layer may be formed from a substantially non-oxidizable or slowly oxidized metal. Examples of non-oxidizable or slowly oxidizable metals include, but are not limited to, gold, rhodium or nickel, which may prevent oxidation or reaction of the prepared metal surface with external environmental factors. Another metal stack that may be used to provide a solderable surface on semiconductors is Ti-Pt-Au.

In an embodiment, the carbon foam material may be sputtered with an inert gas to clean the surface. The cleaned carbon foam material surface may then be sputtered with a solder. The sputter coating may extend to a depth of about 2 ligament diameters of the carbon foam. A depth of about 2 ligament diameters may provide metal contact into the carbon foam material to provide thermal transfer from the integrated circuit to the carbon foam material. A ligament diameter may be defined herein as the diameter of the carbon struts that form the open cells of the foam.

The foam may also be metal-coated by a similar procedure as previously described for the integrated circuit. The carbon foam may be metal-coated by using a reactive braze alloy. The alloy may include about 1% to about 10% titanium. These alloys may not require prior metallization of the silicon or carbon.

In an embodiment, sputtering the carbon foam material and the integrated circuit to clean the surfaces and add the solder may be simultaneously conducted. Sputtering is conducted in a vacuum, thereby reducing the possibility of contamination of the carbon foam material and/or the integrated circuit.

In an embodiment, the carbon foam material and the integrated circuit may be coupled using any number of solders as described herein to provide thermal contact. The selection of the solder to use may be determined by the heat sensitivity of the integrated circuit and how high a temperature the integrated circuit may experience during the soldering step before diminished performance of the integrated circuit is evident. In some embodiments, it may be desirable to use a solder such that the soldering temperature remains below the glass transition temperature of the underfill polymer.

Other criteria that may influence the selection of the solder may include the need to provide good thermal contact with minimal stress to the carbon foam or the integrated circuit. During the soldering process, stresses may develop between the integrated circuit and the carbon foam because the two materials have differing coefficients of thermal expansion. The selection of the solder may be influenced by the need to reduce these process stresses. If the process stress is too great, one or both of the components may be damaged. Additionally, fatigue resistance in the solder may be important. As the melting point of a solder is decreased, the fatigue resistance decreases. Minimizing the temperature excursion during the soldering process may reduce process stress between the integrated circuit and the carbon foam material, but fatigue resistance may decrease. U.S. Pat. No. 4,742,024 to Sugimoto, et al. and U.S. Pat. No. 6,195,256 to Tiziani, et al., both of which are incorporated herein by reference, further describe methods of coupling of components to an integrated circuit by soldering.

The soldering process may be conducted by standard methods available to those skilled in the art. Examples of methods for soldering include, but are not limited to, the use of inert atmosphere furnaces, reducing atmosphere furnaces, vacuum furnaces, ultrasonically assisted soldering, and hot plates. Liquid or gas phase fluxes or solder pastes may also be used during the soldering process to provide a stronger solder joint. The open structure of the carbon foam material may allow removal of the flux material after soldering with a solvent rinse.

In an embodiment, the carbon foam material may be coupled to the integrated circuit by other methods (e.g., brazing or electroplating). Brazing techniques may be similar to soldering techniques. Methods of brazing are described in U.S. Pat. No. 4,742,024 to Sugimoto, et al. and U.S. Pat. No. 5,484,964 to Dawson, deceased, et al., both of which are incorporated herein by reference. In an embodiment, electroplating may be used for coupling of the carbon foam material to the integrated circuit. Methods of electroplating to provide metal surfacing are common in the art. Further information on electroplating may be found in U.S. Pat. No. 6,011,313 to Shangguan, et al. and U.S. Pat. No. 6,153,060 to Pommer, et al., both of which are incorporated herein by reference.

In an embodiment, the carbon foam material may be coupled to an integrated circuit by other methods. Other methods include, but are not limited to, the use of thermally conductive adhesives or thermoplastic films. A thermal grease may be used to improve the contact between the carbon foam material and the integrated circuit. Epoxy materials that are thermally conductive may also be used. Further information on coupling of heat sinks to integrated circuits may be found in U.S. Pat. No. 6,069,023 to Bernier, et al., which is incorporated herein by reference.

Additional attachment methods include the use of S-Bond Material® manufactured by Materials Resources and the use of rare earth containing solders as described in Harish Mavoori, Ainissa G. Ramirez and Sungho Jin, “Universal solders for direct and powerful bonding on semiconductors, diamond, and optical materials” Applied Physics Letters, Volume 78, Number 19, May 7, 2001, pp 2976-2978. A universal solder may be defined herein as a eutectic solder doped with rare earth elements that is used to couple dissimilar materials without using surface treatments on the dissimilar materials.

Referring to FIG. 3, in an embodiment, carbon foam material 17 may be coupled to integrated circuit 13, on substrate 12, by solder 15. Silicide 14 and metal 16 may be present. The carbon foam material may be substantially enclosed within chamber 18. Conduit 19 may be included to direct a cooling fluid into and out of the chamber. The chamber may be coupled to the integrated circuit by mechanical means such as, but not limited to, screws or other mechanical fasteners. Information on non-solderable coupling may be found in U.S. Pat. No. 6,181,006 to Ahl, et al., which is incorporated herein by reference.

In an embodiment, a heat exchange fluid may be used to assist in removal of the heat released by the integrated circuit into the carbon foam material. Heat exchange fluids include, but are not limited to, ambient air, inert gases, gaseous hydrocarbons, halocarbons, or any other material that may be present as a gas through a relatively wide range of temperatures. Liquid heat exchange fluids may also be used. Liquid heat exchange fluids may include fluids such as, but not limited to, glycols, hydrocarbons, halocarbons, or silicone oils.

In an embodiment, fans may be used to direct heat exchange fluids through the carbon foam material. The carbon foam material may provide a path through which the heat exchange fluid passes. In an embodiment, fans may be situated within a computer system such that the heat exchange fluid is directed through the carbon foam material. Conversely, the heat exchange fluid may circulate around and through the carbon foam material as it generally circulates throughout the computer system.

Referring again to FIG. 3, carbon foam material 17 may be substantially enclosed within chamber 18 such that the heat exchange fluid may be directed through the carbon foam material. In an embodiment, a gaseous heat exchange fluid may be directed by the use of conduit 19 into the chamber such that the gaseous heat exchange fluid is directed through the carbon foam material. U.S. Pat. No. 6,143,977 to Kitahara, et al., which is incorporated herein by reference, further describes directed cooling airflow in heat-generating systems.

Heat exchange fluids may also include liquid materials. Referring to FIG. 3, a liquid heat exchange fluid may be directed to and through carbon foam material 17 by a system of conduits 19. In the case of liquid heat exchange fluids, methods of storing, cooling, and transporting the fluid may be added. Reservoir 21 may store the liquid heat exchange fluid. Convective type devices 22 within the liquid heat exchange transport system may cool the liquid heat exchange fluid. Pump 20 may circulate the liquid heat exchange fluid throughout the cooling system.

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed is:

1. A system comprising:
an integrated circuit; and
a carbon foam material thermally coupled to the integrated circuit such that thermal energy from the integrated circuit is transferred to the carbon foam material.

2. The system of claim 1, wherein the carbon foam material comprises graphitic carbon foam material.

3. The system of claim 1, wherein the carbon foam material is coated with a solder.

4. The system of claim 1, wherein the carbon foam material is coated with a solder to a depth of at least two carbon foam ligament diameters into the body of the carbon foam material.

5. The system of claim 1, wherein the carbon foam material is coated with a reactive braze alloy.

6. The system of claim 5, wherein the braze alloy comprises about 1% to about 10% by weight of titanium.

7. The system of claim 1, wherein the integrated circuit is coated with a metal silicide.

8. The system of claim 7, wherein the metal silicide is coated with an adherent metal.

9. The system of claim 1, wherein the carbon foam material is coupled to the integrated circuit by solder, and wherein the solder comprises copper, nickel, gold, silver, lead, silicon, indium, bismuth, titanium, tin, or mixtures thereof.

10. The system of claim 1, wherein the carbon foam material is coupled to the integrated circuit by a universal solder.

11. The system of claim 1, wherein the carbon foam material is coupled to the integrated circuit by adhesives.

12. The system of claim 1, wherein the carbon foam material is disposed within a chamber.

13. The system of claim 12, further comprising conduits coupled to the chamber, wherein the conduits are configured to direct a heat exchange fluid into the chamber.

14. A method of coupling a carbon foam material to an integrated circuit comprising:
coupling the carbon foam material to the integrated circuit such that thermal energy from the integrated circuit is transferred to the carbon foam material.

15. The method of claim 14, wherein the surface of the integrated circuit is cleaned.

16. The method of claim 14, further comprising cleaning the surface of the integrated circuit by backsputtering the surface of the integrated circuit with an inert gas.

17. The method of claim 14, wherein the surface of the carbon foam material is cleaned.

18. The method of claim 14, further comprising cleaning the surface of the carbon foam material by backsputtering with an inert gas.

19. The method of claim 14, further comprising coating the surface of the integrated circuit with a solder.

20. The method of claim 14, further comprising coating the surface of the carbon foam material with a solder.

21. The method of claim 14, further comprising coupling the integrated circuit and the carbon foam material with a solder.

22. The method of claim 14, further comprising coupling the integrated circuit and the carbon foam material with a solder, wherein the solder comprises copper, nickel, gold, silver, lead, silicon, indium, bismuth, titanium, tin, or mixtures thereof.

23. The method of claim 14, further comprising coupling the integrated circuit and the carbon foam material with a universal solder.

24. The method of claim 14, further comprising coupling the integrated circuit and the carbon foam material with adhesives.

25. The method of claim 14, further comprising forming a silicide on the surface of the integrated circuit.

26. The method of claim 25, further comprising coating the surface of the silicide comprises with an adherent metal.

27. The method of claim 14, wherein coupling the carbon foam material to the integrated circuit further comprises heating the carbon foam material with the integrated circuit in an inert atmosphere furnace.

28. The method of claim 14, wherein coupling the carbon foam material to the integrated circuit further comprises heating the carbon foam material with the integrated circuit in a reducing atmosphere furnace.

29. The method of claim 14, wherein coupling the carbon foam material to the integrated circuit further comprises heating the carbon foam material with the integrated circuit in a vacuum furnace.

30. The method of claim 14, wherein coupling the carbon foam material to the integrated circuit further comprises heating the carbon foam material with the integrated circuit on a hot plate.

31. A system comprising:
a computer with an integrated circuit, wherein a carbon foam material is thermally coupled to the integrated circuit such that thermal energy from the integrated circuit is transferred to the carbon foam material.
